(19) United States
(12) Patent Application Publication
(10) Pub. No.: US 2008/0118998 A1
(43) Pub. Date: May 22, 2008

(54) Method for enhancing lightness of p-type nitride group compound L.E.D.

(75) Inventors: Ray-Ming Lin, Tao-Yuan (TW); Kuo-Hsing Chen, Tao-Yuan (TW); Jen-Chih Li, Tao-Yuan (TW); Yi-Lun Chou, Tao-Yuan (TW)

Correspondence Address: BACON & THOMAS, PLLC, 625 SLATERS LANE, FOURTH FLOOR, ALEXANDRIA, VA, 22314, US

(73) Assignee: Chang Gung University, Tao-Yuan (TW)

(21) Appl. No.: 11/603,068

(22) Filed: Nov. 22, 2006

(51) Int. Cl. H01L 21/00

(52) U.S. Cl. 438/46

(57) ABSTRACT

A method for enhance lightness of p-type nitride group compound L.E.D. is disclosed. The present invention, firstly, the p-type GaN semiconductor layer is provided, then, the different thickness and coverage for titanium metal are coated on the p-type GaN semiconductor layer. Next, the activation process is carried out in the heating tube under the nitrogen gas and quite high temperature, about certain minutes. Finally, The titanium metal is removed after the activation process, therefore the carrier concentration can be selectively changed, in order to enhance lightness for p-type nitride group compound L.E.D.

### BACKGROUND OF THE INVENTION

1. Field of the Invention

The invention relates to enhance lightness of p-type nitride group compound L.E.D., more particularly for applying to the p-type nitride group compound L.E.D., by changing carrier concentration in order to enhance lightness.

2. Description of the Prior Art

Now light emitting device (L.E.D.) is a revolution-effect production after the electronic transistor and the laser L.E.D. appeared by the semiconductor technology development. Therefore the better result can be shown as the followings. Firstly, the lifetime of L.E.D. light bulb can be longer than the normal light bulb about 50 to 100 folds. Secondly, the power consumption of L.E.D. is about ⅓ to ⅕ than the normal light bulb in the 21st century. Also, it is possible to become a new lighting source coupled with electricity saving and green concept instead of the tungsten-filament lamp and the mercury lamp.

The L.E.D. display would become full-colour and the access density for the video compact disc would be increased when the technology of the blue, green L.E.D. can gradually become mature. This will be key-development materials.

The blue L.E.D. is one of the important type for the L.E.D. group. Until now, the world industry are still actively developing forward into the more high brightness blue L.E.D.

Recently, all of the advanced countries actively invest in the research plan for development of the photoelectric semiconductor GaN. The one candle brightness blue L.E.D. is successfully developed. Also, this made L.E.D. can enter the full-colour time; it can provide higher brightness blue L.E.D. for the industry need. The photoelectric semiconductor GaN can apply to the full-colour outside displays and the traffic lights.

The leading company in the industry, as Japanese Nichia Chemical Company, announced that they have successfully developed the blue, green high brightness InN, GaN L.E.D. (wavelength is about 520 nanometer) in October, 1995. In the end of 1998, the blue laser L.E.D. that can continuously operated and lifetime can be about 10000 hours were successfully developed. In the blue, green L.E.D. research and development, and mass-production field, Japanese Nichia Chemical Company also owns the many more patents all over the world.

It is worth to mentioned, about the application patent for the high brightness GaN and the white L.E.D. chip materials and related element structure are hold by the Japanese Nichia Chemical company.

Blue light L.E.D. is one of the important types for many of the L.E.D. groups. In many of the Blue light L.E.D. materials, wherein the GaN can be made for ultraviolet L.E.D., due to as the short wavelength illuminant, belong to high energy illuminant, also can be applied to medical, food treatment, and greenhouse cultivation.

In the traditional manufacturing process for the GaN blue L.E.D., such as U.S. Pat. No. 6,996,150, “Semiconductor light emitting device and manufacturing method therefore”, U.S. Pat. No. 6,998,690, “Gallium nitride based III-V group compound semiconductor device and method of producing the same”, and U.S. Pat. No. 6,984,536, “Method for manufacturing a gallium nitride group compound semiconductor”, there are some manufacturing processes for manufacturing GaN blue L.E.D but unfortunately, there is no any other method for enhancing blue brightness of L.E.D.

In Taiwan patent No. M279022, Inotera Memories, Inc. owns “having metal-oxidation conductive layer L.E.D.”, even though points out forming a good ohm contact method, there is no way to enhance the brightness of L.E.D. method.

### SUMMARY OF THE INVENTION

In accordance with the present invention, a method is provided for enhancing lightness of p-type gallium nitride (GaN) compound L.E.D. by breaking through the conventional semiconductor manufacture technology.

The foregoing, as well as additional objects, features and advantages of the invention will be more readily apparent from the following detailed description, which proceeds with reference to the accompanying drawings.

Firstly, the present invention, the p-type gallium nitride (GaN) semiconductor layer is provided as the base.

Then, the different thickness and coverage for titanium metal are coated on the p-type gallium nitride (GaN) semiconductor layer by the electric coating machine. The different thickness for above coating is about 50 nm, 100 nm, 150 nm, 200 nm and 250 nm. Also, the coverage can be coated on the different area.

Next, the activation process is carried out in the heating tube under the nitrogen gas and quite high temperature that is around 600° C. to 800° C., the preferred temperature is about 700° C., in the certain minute that is around 20 to 40 minutes, the preferred minute is about 30 minutes. This step is for activation the p-type gallium nitride (GaN) semiconductor and titanium metal.

Finally, the titanium metal is removed after the activation process, then, the titanium metal is removed from the surface of p-type gallium nitride (GaN) by using the BOE chemical liquid. Therefore the carrier concentration can be selectively changed, in order to enhance lightness for the blue p-type nitride group compound L.E.D.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

TABLE 1 shows the comparison result for the different metal selected testing;

FIG. 1 is a flow-chart schematically illustrating the embodiment of the invention;

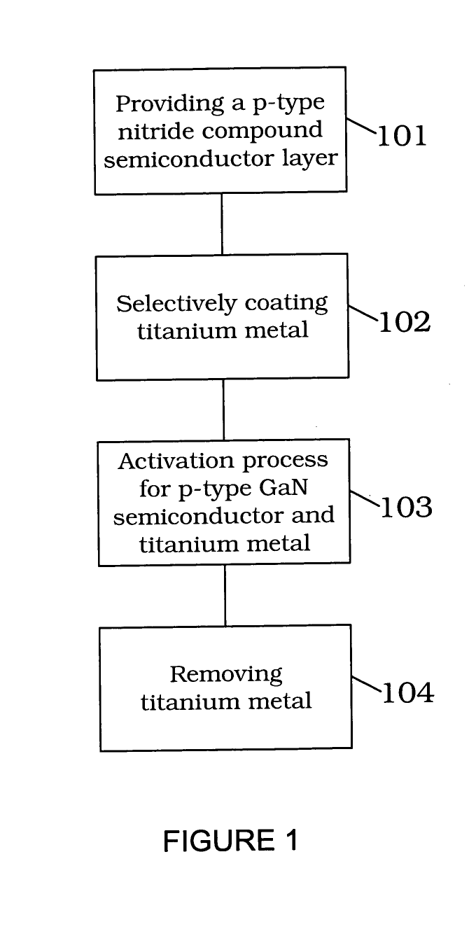

FIG. 2 is illustrative of carrier concentration test with the embodiment of the present invention;

FIG. 3 is schematic diagrams showing the leakage current test of the embodiment of present invention; and

FIG. 4 shows schematic diagrams of intensity enhancement test in the embodiment.

### DESCRIPTION OF THE PREFERRED EMBODIMENT

The following is a description of the present invention. The invention will firstly be described with reference to one exemplary structure. Some variations will then be described as well as advantages of the present invention. A preferred method of fabrication will then be discussed. An alternate, asymmetric embodiment will then be described along with the variations in the process flow to fabricate this embodiment.

A method for enhance lightness of gallium nitride (GaN) compound L.E.D. is disclosed. The present invention, firstly, the p-type gallium nitride (GaN) semiconductor layer is provided, then, the different thickness and coverage for titanium metal are coated on the p-type gallium nitride (GaN) semiconductor layer. Next, the activation process is carried out in the heating tube under the nitrogen gas and quite high temperature, about certain minutes. Finally, The titanium metal is removed after the activation process, therefore the carrier concentration can be selectively changed, in order to enhance lightness for p-type nitride group compound L.E.D.

For the technology development and research for this invention, the selection for the coated metal is the first consideration.

In the first step, the p-type gallium nitride(GaN)semiconductor layer is provided as the base, also is for the species. Then the different kind of metal are selected including titanium(Ti), titanium/gold(Ti/Au), gold(Au), silver(Ag) and copper(Cu), and coated by the E-beam evaporation on the surface of p-type gallium nitride (GaN) semiconductor layer. Also, the thickness for these metals is as follows: the thickness for titanium (Ti) is about 200 nm; the thickness for titanium/gold(Ti/Au) is about 100 nm/100 nm; the thickness for gold(Au) is about 200 nm; the thickness for silver(Ag) is about 200 nm and the thickness for copper(Cu) is about 200 nm.

After the activation process under 700° C., the electrical hole concentration is measured by the Hall Measurement system, the measurement result can be obtained as the table 1 illustrating:

the measurement result for titanium (Ti) is about 3.31×10¹⁶ cm⁻³;
the measurement result for titanium/gold(Ti/Au) is about 5.75×10¹⁶ cm⁻³;
the measurement result for gold(Au) is about 6.37×10¹⁶ cm⁻³;
the measurement result for silver(Ag) is about 1.12×10¹⁷ cm⁻³;
the measurement result for copper(Cu) is about 2.36×10¹⁷ cm⁻³; and the measurement result for p-type gallium nitride (GaN) semiconductor layer is about 3.45×10¹⁷ cm⁻³.

Therefore, as the result, the titanium metal can be effectively useful for reducing the electrical hole concentration of p-type gallium nitride (GaN) under the condition as temperature is about 700° C. and time is about 30 minutes.

The invention, a method for enhance lightness of p-type nitride group compound L.E.D. is disclosed. The present invention, firstly, the p-type GaN semiconductor layer is provided, then, the different thickness and coverage for titanium metal are coated on the p-type GaN semiconductor layer. Next, the activation process is carried out in the heating tube under the nitrogen gas and quite high temperature, about certain minutes. Finally, The titanium metal is removed after the activation process, therefore the carrier concentration can be selectively changed, in order to enhance lightness for p-type nitride group compound L.E.D.

Comparing with the conventional manufacture process for increasing electric conductivity, this invention can reduce the electrical hole concentration about to 1/10. Therefore the titanium metal can be the selected metal for reducing the electrical hole concentration, also can reduce the electric conductivity concentration and can be as one of the electrical current limitation method.

After the titanium metal is definitely selected as the metal for reducing the electrical hole concentration, this invention can be as follows.

As FIG. 101, firstly, for the present invention, the p-type gallium nitride (GaN) semiconductor layer is provided as the base.

Then, as FIG. 102, the different thickness and coverage for titanium metal are selectively coated on the p-type GaN semiconductor layer by the E-beam evaporation. This selective coating can decide the coverage area and the coverage size; also the different thickness can be decided. The different thickness of titanium metal for above coating is about 50 nm, 100 nm, 150 nm, 200 nm and 250 nm, respectively.

Next, as FIG. 103, the activation process is carried out in the heating tube, isolated oxygen gas, such as under the nitrogen gas and quite high temperature that is around 600° C. to 800° C., the preferred temperature is about 700° C., in the certain minute that is around 20 to 40 minutes, the preferred minute is about 30 minutes. This step is for activating the p-type gallium nitride (GaN) semiconductor layer and titanium metal.

The final step, FIG. 104 shows that after the activation process, the titanium metal is removed from the surface of p-type gallium nitride (GaN) by using the BOE (NH₄F:HF=6:1) chemical liquid. Due to the related chemical character, the BOE would be preferred used for the invention, but some other chemical etching liquids could be used for this etching step. Therefore the carrier concentration can be selectively changed, in order to enhance lightness for the blue p-type gallium nitride(GaN)compound L.E.D., i.e., also for the blue p-type nitride group compound L.E.D.

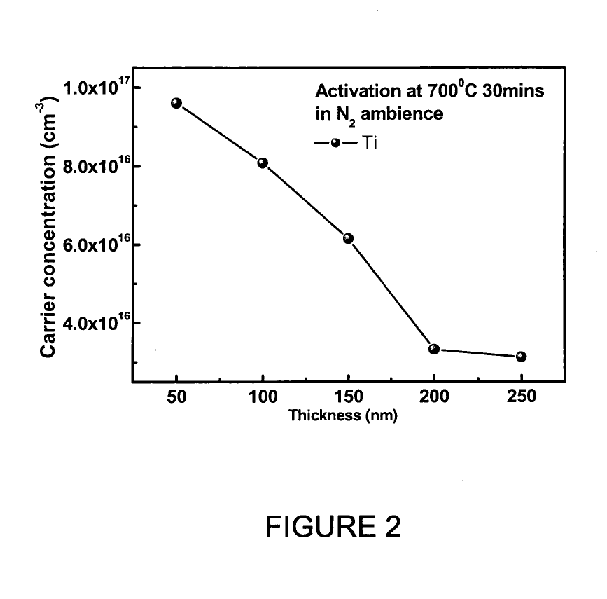

Consequently, some testing are carried out, such as FIG. 2, it shows the Hall Measurement result, the result of Carrier Concentration is designed as the vertical line, the different thickness of the titanium metal is designed as the transverse line. Thus, the drawing is formed and the different result are obtained as followings:

### When the coating thickness is 50 nm, the result of Carrier Concentration is about 9.6×10⁶ cm⁻³;

### When the coating thickness is 100 nm, the result of Carrier Concentration is about 8.1×10¹⁶ cm⁻³;

### When the coating thickness is 150 nm, the result of Carrier Concentration is about 6.2×10¹⁶ cm⁻³;

### When the coating thickness is 200 nm, the result of Carrier Concentration is about 3.3×10¹⁶ cm⁻³; and

### When the coating thickness is 250 nm, the result of Carrier Concentration is about 3.1×10¹⁶ cm⁻³.

From observation of the above results, the more higher thickness of titanium metal, the electrical carrier concentration for the p-type gallium nitride (GaN) compound would be lower.

The main reason for activating the p-type gallium nitride(GaN) compound, due to when the p-type gallium nitride (GaN) compound is under the epitaxy wafer process, the magnesium (Mg) ions would be dopanted into the above compound in order to rise the carrier concentration. It is mentioned that the carrier gas is hydrogen(H) gas, thus when the epitaxy wafer process is carried out, so that the Mg—H bonding is formed. The Mg—H gas should be broken into under 700° C. and nitrogen gas for raising up the carrier concentration. However, if the titanium metal could be coated on the p-type gallium nitride (GaN) compound and processed the activation process in the high temperature, then the carrier concentration would be effectively reduced.

Due to the electricity of semiconductor is mutual compensated, the titanium ions after diffusion will be as donors in the gallium nitride (GaN) compound, the acceptor concentration made of the titanium metal below the concentration of magnesium(Mg)impurities, the donor made of titanium ions can compensate parts of the acceptors, so that the carrier concentration will be reduced than before the un-diffusion p-type the gallium nitride (GaN) compound.

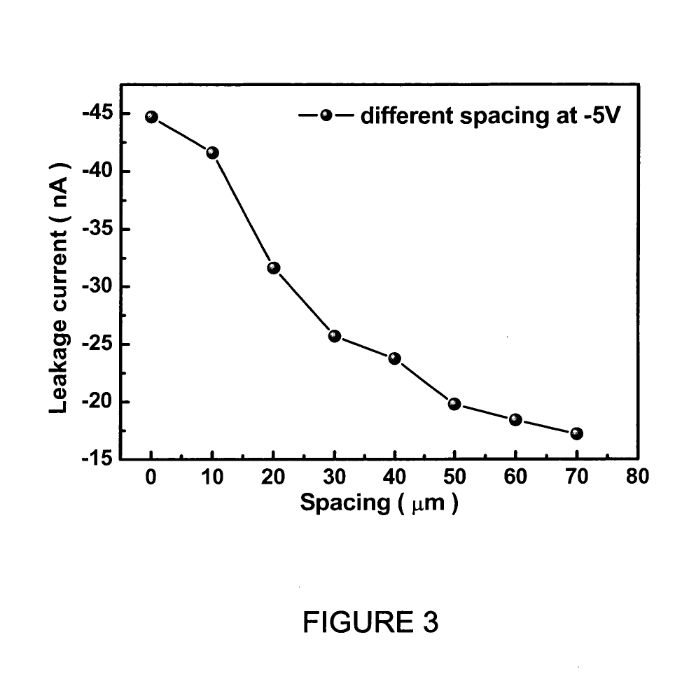

In this invention, there is the outside area around the selectively activation area made by the titanium metal, that is called as High Resistive Region, also is Spacing. Thus, the Leakage Current can be designed as vertical line and the spacing can be the transverse line, then the drawing is formed. As FIG. 3, the result of the element measurement are as the followings, when the elements operation voltage is about −5 volts, spacing will be as:

### When spacing is about 0 μm, Leakage Current is about −4.47×10⁻⁸ A;

### When spacing is about 10 μm, Leakage Current is about −4.16×10⁻⁸ A;

### When spacing is about 20 μm, Leakage Current is about −3.16×10⁻⁸ A;

### When spacing is about 30 μm, Leakage Current is about −2.57×10⁻⁸ A;

### When spacing is about 40 μm, Leakage Current is about −2.37×10⁻⁸ A;

### When spacing is about 50 μm, Leakage Current is about −1.98×10⁻⁸ A;

### When spacing is about 60 μm, Leakage Current is about −1.84×10⁻⁸ A;

and when spacing is about 70 μm, Leakage Current is about −1.72×10⁻⁸ A.

Therefore, the more increase of the spacing, of the leakage current is less, especially the curve until 60 μm to 70 μm shows the gentle trend. The selective activation L.E.D. can effectively improve the perfect damage of the epitaxy wafer passed by the ICP-RIE (Reactive Ion Etching) dry system etching and the grain cleavage damage by cutting, also can be improved the p-type perfect. These perfects form by the electrical current of elements from p electrode from the surface side-wall to the n electrode, and the carrier will be catched, it will reduce the carrier passing through the activation layer, also will reduce the complex emitting mechanism reaction of the attend carrier.

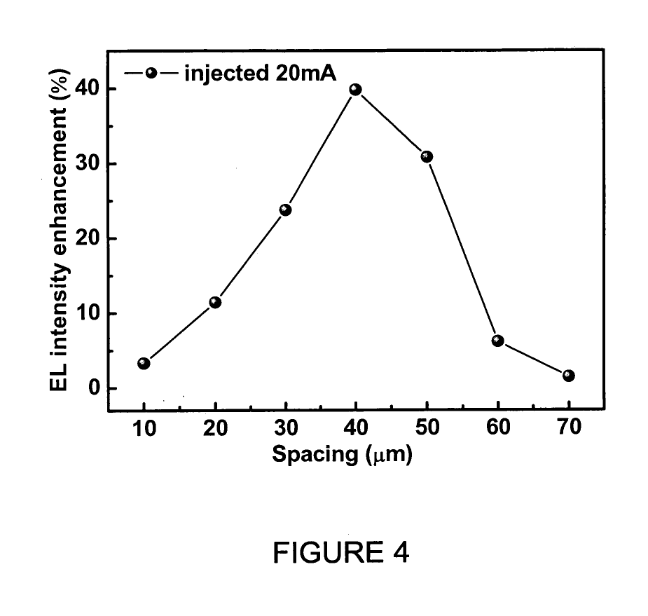

FIG. 4 shows that the selective activation elements made by the present invention, when the operation electrical current is set up in 20 mA, the intensity enhancement percentage is for emitting brightness of the electric luminescence (E.L.). The intensity enhancement is vertical line and the spacing is the transverse line. At the different spacing from the FIG. 4, such as 10 μm, 20 μm, 30 μm, 40 μm, 50 μm, 60 μm and 70 μm, the intensity enhancement percentage can be increased to 3.3%, 11.4%, 23.7%, 39.8%, 30.8%, 6.2%, 1.4%, respectively.

Such as FIG. 4, when the spacing is changed to 40 μm, brightness can be increased to 40%, the more spacing and brightness will be less. It is supposed that the electrical current limitation effect will be more obvious when the elements attending the emitting complex mechanism area is small under a stable input electrical current. Also, if the emitting areas are smaller, the heating effect phenomenon will be more obvious. It will cause brightness reducing and the wavelength will move to the long-wavelength direction, i.e. a red shift phenomenon.

The present invention technology can be applied for the L.E.D. manufacture process; also the invention can excite the fluorescent layer using the blue light. The previous fluorescent layer can be excited up the luminescence and the wavelength of luminescence is between about 500˜570 nm. Therefore, the invention can produce the higher blue brightness and related technology can be used to the p-type nitride group compound light emitting device.

It is understood that various other modifications will be apparent to and can be readily made by those skilled in the art without departing from the scope and spirit of this invention. Accordingly, it is not intended that the scope of the claims appended hereto be limited to the description as set forth herein, but rather that the claims be construed as encompassing all the features of patentable novelty that reside in the present invention, including all features that would be treated as equivalents thereof by those skilled in the art to which this invention pertains.

What is claimed is:

1. A method for enhancing lightness of a p-type nitride group compound light emitting device, comprising:
providing a p-type nitride compound group semiconductor layer as a base and selectively coating a different thickness and a coverage of a metal on the p-type gallium nitride (GaN) semiconductor layer;
carrying out a activation process in a heating tube under a nitrogen gas and a quite certain temperature, about certain minutes to active the metal and the p-type gallium nitride compound semiconductor layer;
removing the metal from surface of the p-type gallium nitride (GaN) after the activation process, therefore the carrier concentration is selectively changed in order to enhance lightness for the p-type nitride group compound light emitting device.

2. The method according to claim 1, wherein said p-type nitride compound group semiconductor layer comprises a gallium nitride (GaN) semiconductor layer.

3. The method according to claim 2, wherein said gallium nitride (GaN) semiconductor layer comprises p-type GaN semiconductor layer.

4. The method according to claim 1, wherein said selectively coating comprises using a coating machine to produce a different thickness of said metal.

5. The method according to claim 4, wherein said selectively coating comprises using an electronic coating machine to produce a different thickness of said metal.

6. The method according to claim 1, wherein said selectively coating comprises using a coating machine to produce a different coverage of said metal.

7. The method according to claim 6, wherein said selectively coating comprises using an electronic coating machine to produce a different coverage of said metal.

8. The method according to claim 1, wherein the condition for said activation process comprises under nitrogen gas, 600° C. to 800° C., 20 to 40 minutes.

9. A method for enhancing lightness of a p-type gallium nitride (GaN) compound light emitting device, comprising:
providing a p-type gallium nitride compound semiconductor layer as a base;
selectively coating a different thickness and a coverage of a metal on the p-type gallium nitride compound semiconductor layer;
carrying out a activation process in a heating tube for under a nitrogen gas and a quite certain temperature, about certain minutes in order to active the metal and the p-type gallium nitride compound semiconductor layer;
removing the metal from surface of the p-type gallium nitride(GaN) after the activation process, therefore the carrier concentration is selectively changed in order to enhance lightness for the p-type nitride group compound light emitting device.

10. The method according to claim 9, wherein said selectively coating comprises using a coating machine to produce a different thickness of said metal.

11. The method according to claim 10, wherein said selectively coating comprises using an electronic coating machine to produce a different thickness of said metal.

12. The method according to claim 9, wherein said selectively coating comprises using a coating machine to produce a different thickness of said metal.

13. The method according to claim 12, wherein said selectively coating comprises using an electronic coating machine to produce a different coverage of said metal.

14. The method according to claim 9, wherein the condition for said activation process comprises under nitrogen gas, 600° C. to 800° C., 20 to 40 minutes.
